(19) United States
(12) Patent Application Publication
(10) Pub. No.: US 2020/0176424 A1
(43) Pub. Date: Jun. 4, 2020

(54) SEMICONDUCTOR APPARATUS

(71) Applicant: SUMITOMO ELECTRIC INDUSTRIES, LTD., Osaka (JP)

(72) Inventor: Hisato MICHIKOSHI, Ibaraki (JP)

(21) Appl. No.: 16/620,658

(22) PCT Filed: Feb. 6, 2018
(86) PCT No.: PCT/JP2018/004082

§ 371 Date: Dec. 9, 2019

(30) Foreign Application Priority Data
Jun. 20, 2017 (JP) 2017-120263

(51) Int. Cl. H01L 25/07; H01L 23/00

(52) U.S. Cl. CPC H01L 25/072; H01L 2224/48227; H01L 2224/48137; H01L 24/48

(57) ABSTRACT

A semiconductor apparatus includes an electrode terminal, a substrate disposed on the electrode terminal and made of an insulating material, a first power semiconductor device disposed on the electrode terminal, and a second power semiconductor device disposed on the substrate, wherein the first power semiconductor device and the second power semiconductor device are connected in series.

### TECHNICAL FIELD

The disclosures herein relate to a semiconductor apparatus.

The present application claims priority to Japanese patent application No. 2017-120263 filed on Jun. 20, 2017, and the entire contents of this Japanese patent application are hereby incorporated by reference.

### BACKGROUND ART

Semiconductor devices such as diodes and MOSFETs (metal-oxide-semiconductor field-effect transistors) are used in a variety of applications, and have differing required properties depending on the application in which they are used. Some of such semiconductor devices are used for high-voltage applications. Since the voltage tolerance of a single semiconductor device is limited, measures may be taken to connect a plurality of semiconductor devices in series (for example, Patent Document 1).

### RELATED-ART DOCUMENTS

### Patent Document

[Patent Document 1] Japanese Patent Application Publication No. 2016-208706

### SUMMARY OF THE INVENTION

According to one aspect of the present embodiment, a semiconductor apparatus includes an electrode terminal, a substrate disposed on the electrode terminal and made of an insulating material, a first power semiconductor device disposed on the electrode terminal, and a second power semiconductor device disposed on the substrate, wherein the first power semiconductor device and the second power semiconductor device are connected in series.

### BRIEF DESCRIPTION OF DRAWINGS

FIG. 1A is a top view of a semiconductor apparatus according to one aspect of the present disclosures.

FIG. 1B is a bottom view of the semiconductor apparatus according to the one aspect of the present disclosures.

FIG. 1C is a side elevation view of the semiconductor apparatus according to the one aspect of the present disclosures.

FIG. 2 is an illustrative drawing (1) of the semiconductor apparatus according to the one aspect of the present disclosures.

FIG. 3 is an illustrative drawing (2) of the semiconductor apparatus according to the one aspect of the present disclosures.

FIG. 4A is a cross-sectional view (1) of the semiconductor apparatus according to the one aspect of the present disclosures.

FIG. 4B is a cross-sectional view (2) of the semiconductor apparatus according to the one aspect of the present disclosures.

FIG. 5A is a top view of a substrate used in the semiconductor apparatus according to the one aspect of the present disclosures.

FIG. 5B is a bottom view of the substrate used in the semiconductor apparatus according to the one aspect of the present disclosures.

FIG. 5C is a cross-sectional view of the substrate used in the semiconductor apparatus according to the one aspect of the present disclosures.

FIG. 6 is an illustrative drawing of a variation 1 of the semiconductor apparatus according to the one aspect of the present disclosures.

FIG. 7 is an illustrative drawing of a variation 2 of the semiconductor apparatus according to the one aspect of the present disclosures.

### MODE FOR CARRYING OUT THE INVENTION

Unfortunately, in the case of semiconductor equipment employing a plurality of semiconductor devices for the purpose of improving voltage tolerance, the semiconductor equipment may become cumbersome.

Accordingly, the purpose of the present disclosures is to provide a small-size high-voltage semiconductor apparatus that uses a plurality of semiconductor devices.

Embodiments will be described in the following.

### DESCRIPTION OF EMBODIMENTS OF THE PRESENT DISCLOSURE

Embodiments of the present disclosures will be listed and described first. In the following description, the same or corresponding elements are referred to by the same reference numerals, and a duplicate description thereof will be omitted.

[1] A semiconductor apparatus according to an embodiment of the present disclosures includes an electrode terminal, a substrate disposed on the electrode terminal and made of an insulating material, a first power semiconductor device disposed on the electrode terminal, and a second power semiconductor device disposed on the substrate, wherein the first power semiconductor device and the second power semiconductor device are connected in series.

The inventors of the present application have found that disposing a substrate made of an insulating material on an electrode terminal, disposing a first power semiconductor device on the electrode terminal, disposing a second power semiconductor device on the substrate, and connecting the first power semiconductor device and the second power semiconductor device in series allows the first power semiconductor device and the second power semiconductor device to be brought closer to each other by an amount equal to at least the thickness of the substrate. This arrangement serves to downsize a high-voltage semiconductor apparatus.

[2] A third power semiconductor device disposed on the substrate is provided, wherein the first power semiconductor device, the second power semiconductor device, and the third power semiconductor device are connected in series.

[3] A plurality of electrode patterns are formed on a surface of the substrate, wherein the second power semiconductor device and the third power semiconductor device are disposed on and connected to the respective electrode patterns, and wherein a shape of the electrode patterns includes a curved line.

[4] A fourth power semiconductor device disposed on the substrate is provided, wherein the first power semiconductor device, the second power semiconductor device, the third power semiconductor device, and the fourth power semiconductor device are connected in series, and wherein the second power semiconductor device, the third power semiconductor device, and the fourth power semiconductor device are aligned in a straight line on the substrate.

[5] The insulating material includes at least one kind selected from aluminum nitride, silicon nitride, silicon carbide, and diamond.

[6] The power semiconductor devices are made of an SiC semiconductor.

### DETAILS OF EMBODIMENTS OF THE PRESENT DISCLOSURE

In the following, an embodiment (hereinafter referred to as a present embodiment) of the present disclosures will be described in detail, with a caveat that the present embodiment is not limited to those described.

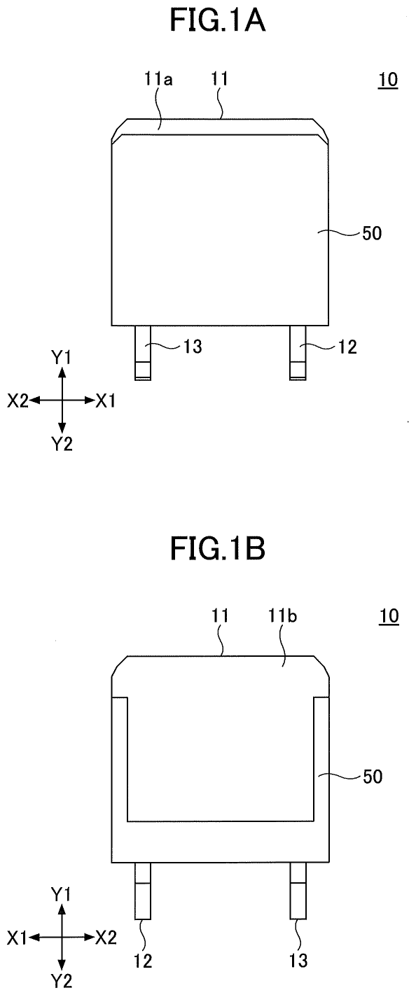

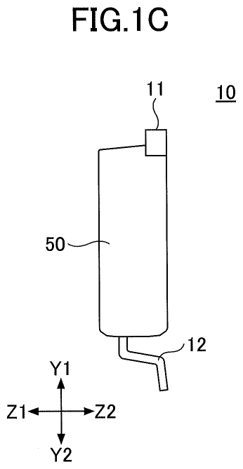

A semiconductor apparatus according to the present embodiment will be described with reference to FIG. 1 through FIG. 4. The semiconductor apparatus according to the present embodiment is a high-voltage diode in which a plurality of a semiconductor diode chips are connected in series to achieve a high-voltage-tolerance structure.

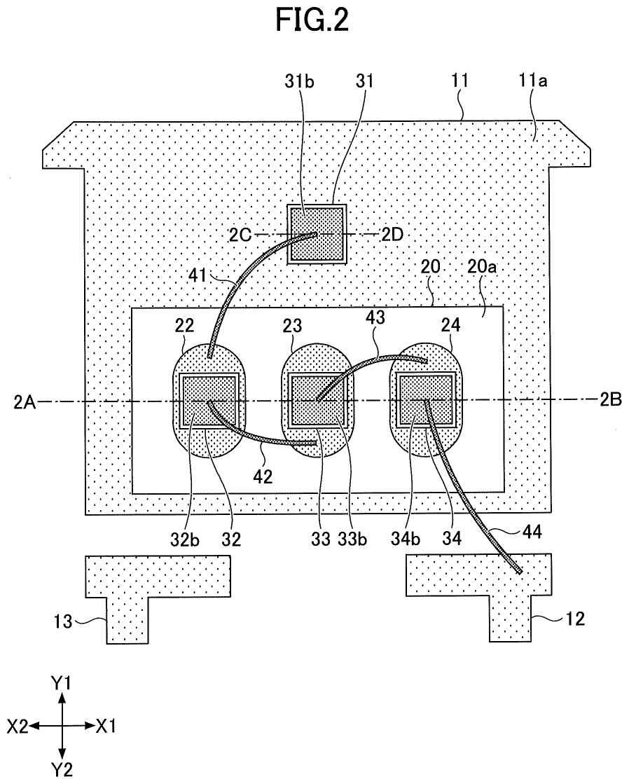

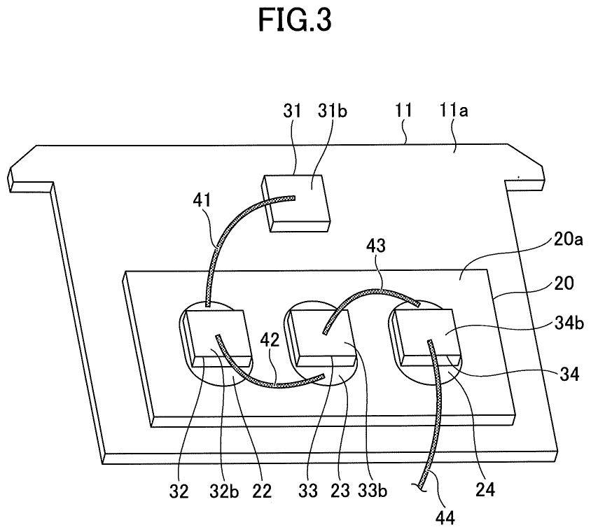

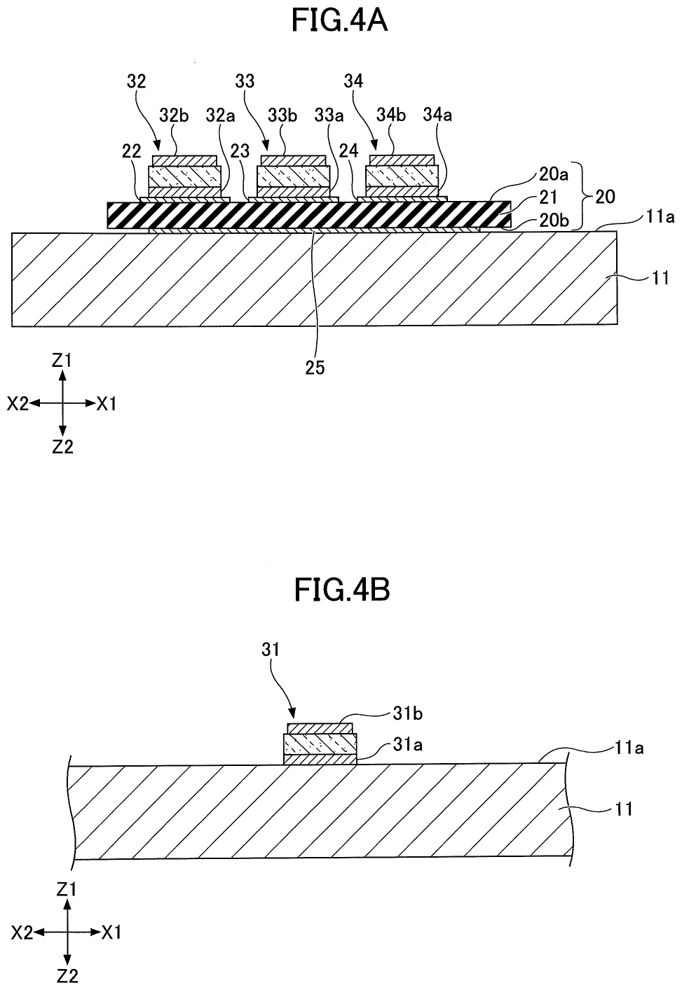

FIG. 1A is a top view of the appearance of the semiconductor apparatus according to the present embodiment. FIG. 1B is a bottom view. FIG. 10 is a side-elevation view. FIG. 2 is a top view of the semiconductor device of the present embodiment as appears upon molded resin being removed. FIG. 3 is an oblique view of the main part. FIG. 4A is a cross-sectional view taken along the dot-and-dash line 2A-2B in FIG. 2. FIG. 4B is a cross-sectional view taken along the dot-and-dash line 2C-2D in FIG. 2. In FIG. 4A and FIG. 4B, bonding wires and the like are omitted.

A semiconductor apparatus 10 of the present embodiment includes a first electrode terminal 11, a second electrode terminal 12, a substrate 20 made of an insulating material, a first semiconductor chip 31, a second semiconductor chip 32, a third semiconductor chip 33, a fourth semiconductor chip 34, and the like. In the present application, a semiconductor chip may sometimes be referred to as a semiconductor device. A third electrode terminal 13 will be described later.

In the present embodiment, the first semiconductor chip 31, the second semiconductor chip 32, the third semiconductor chip 33, and the fourth semiconductor chip 34 are high-voltage-application diodes made of a semiconductor material such as an SiC semiconductor that has a wider bandgap than Si. Each of the first semiconductor chip 31, the second semiconductor chip 32, the third semiconductor chip 33, and the fourth semiconductor chip 34 has a cathode electrode formed on a first face and an anode electrode formed on a second face. The shape of the first and second faces is substantially a square with a side of 1.5 mm.

The first electrode terminal 11 and the second electrode terminal 12 are made of Cu (copper), a copper alloy, or the like, with the surface thereof partially or entirely plated with Ni (nickel) In the semiconductor apparatus 10, the first electrode terminal 11 serves as a cathode electrode terminal, and the second electrode terminal 12 serves as an anode electrode terminal.

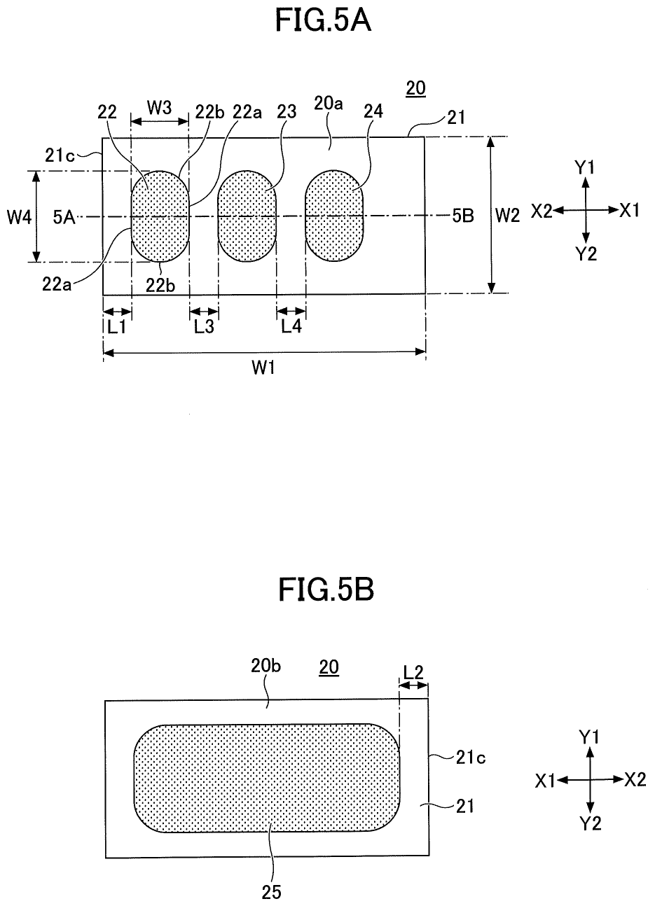

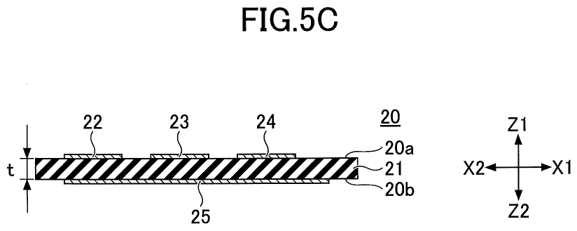

As illustrated in FIG. 5, the substrate 20 has electrode patterns 22, 23, and 24 formed on a first face 20a of the substrate 20 that is a front surface of an insulator substrate 21 made of an insulating material, and has an electrode pattern 25 formed on a second face 20b thereof. It may be noted that FIG. 5A is a top view of the substrate 20, and FIG. 5B is a bottom view thereof, with FIG. 5C being a cross-sectional view taken along the dot-and-dash line 5A-5B. The electrode patterns 22, 23, 24 and 25 are made of copper, a copper alloy, or the like, with the surface thereof being partially or entirely plated with nickel. In the present application, the first face 20a of the substrate 20 may sometimes be referred to as a front surface of the substrate.

The insulator substrate 21 has a rectangular shape with one side having a length W1 of about 11 mm in the X1-X2 direction and another side having a length W2 of about 5.5 mm in the Y1-Y2 direction, with a thickness t of about 0.635 mm in the Z1-Z2 direction. The material constituting the insulator substrate 21 is an insulating material such as aluminum nitride (AlN), silicon nitride (Si₃N₄), aluminum oxide (Al₂O₃), or the like. The most preferred one among these is aluminum nitride. This is because the dielectric withstand voltage is 15-20 kV/mm for aluminum nitride, 10-15 kV/mm for silicon nitride, and 10-15 kV/mm for aluminum oxide, among which the dielectric withstand voltage of aluminum nitride is the highest. The insulator substrate 21 may be made of silicon carbide, diamond, or the like.

The electrode patterns 22, 23, 24 and 25 formed on the substrate 20 are situated in the inner area at a distance of 1 mm or more from a perimeter 21c of the insulator substrate 21 that coincides with the peripheral side surface thereof. Specifically, the minimum distance L1 between the perimeter 21c of the insulator substrate 21 and the electrode pattern or the like as well as the minimum distance L2 between the perimeter 21c of the insulator substrate 21 and the electrode pattern 25 are configured to be greater than or equal to 1 mm. Further, the minimum distance L3 between the electrode pattern 22 and the electrode pattern 23 as well as the minimum distance L4 between the electrode pattern 23 and the electrode pattern 24 are also configured to be greater than or equal to 1 mm. As described above, the electrode patterns are formed at a predetermined distance or greater from the perimeter of the insulator substrate, and are formed such that the electrode patterns are spaced apart at a predetermined distance or greater, thereby maintaining a desired voltage tolerance.

The outer shape of the electrode patterns 22, 23, and 24 is an elongated circular shape with a length W3 of 2 mm in the X1-X2 direction and a length W4 of 3 mm in the Y1-Y2 direction. Specifically, when the electrode pattern 22 is taken as an example, the outline of the electrode pattern 22 is constituted by two straight-line sections 22a extending in the Y1-Y2 direction and curved-line sections 22b connecting the two straight-line sections 22a in the Y1-Y2 direction. Namely, there are no angles. In the present embodiment, the radius of curvature of the curved-line sections 22b constituting the outline of the electrode pattern 22 is 1.0 mm. The electrode patterns 23 and 24 are shaped in the same form as the electrode pattern 22. The use of the outer shape of the electrode patterns 22, 23, and 24 having no angles enables the improvement of dielectric withstand voltage. Namely, since dielectric breakdown and discharge occur due to the concentration of an electric field at the angles of electrodes or the like, the use of an outer shape having no angles as in the case of the electrode patterns 22, 23, and 24 serves to lessen the concentration of an electric field, thereby improving the voltage tolerance.

In the semiconductor device of the present embodiment, the substrate 20 and the first semiconductor chip 31 are mounted on and connected to a first face 11a of the first electrode terminal serving as a die pad, as illustrated in FIG. 2 and FIG. 3. Specifically, as illustrated in FIG. 4, the electrode pattern 25 formed on the second face 20b of the substrate 20 and a cathode electrode 31a formed on the first face of the first semiconductor chip 31 are bonded by solder or the like (not shown) to the first face 11a of the first electrode terminal 11.

The electrode pattern 22 formed on the first face 20a of the substrate 20 has the second semiconductor chip 32 connected thereto. Specifically, a cathode electrode 32a formed on the first face of the second semiconductor chip 32 is bonded by solder or the like (not shown) to the electrode pattern 22 formed on the first face 20a of the substrate 20.

The electrode pattern 23 formed on the first face 20a of the substrate 20 has the third semiconductor chip 33 connected thereto. Specifically, a cathode electrode 33a formed on the first face of the third semiconductor chip 33 is bonded by solder or the like (not shown) to the electrode pattern 23 formed on the first face 20a of the substrate 20.

The electrode pattern 24 formed on the first face 20a of the substrate 20 has the fourth semiconductor chip 34 connected thereto. Specifically, a cathode electrode 34a formed on the first face of the fourth semiconductor chip 34 is bonded by solder or the like (not shown) to the electrode pattern 24 formed on the first face 20a of the substrate 20.

In the semiconductor device of the present embodiment, as illustrated in FIG. 2 and FIG. 3, an anode electrode 31b formed on the second face of the first semiconductor chip 31 and the electrode pattern 22 formed on the first face 20a of the substrate 20 are coupled through a bonding wire 41. With this arrangement, the anode electrode 31b of the first semiconductor chip 31 is electrically coupled to the cathode electrode 32a of the second semiconductor chip 32 via the electrode pattern 22 and the bonding wire 41.

An anode electrode 32b formed on the second face of the second semiconductor chip 32 and the electrode pattern 23 formed on the first face 20a of the substrate 20 are coupled through a bonding wire 42. With this arrangement, the anode electrode 32b of the second semiconductor chip 32 is electrically coupled to the cathode electrode 33a of the third semiconductor chip 33 via the electrode pattern 23 and the bonding wire 42.

An anode electrode 33b formed on the second face of the third semiconductor chip 33 and the electrode pattern 24 formed on the first face 20a of the substrate 20 are coupled through a bonding wire 43. With this arrangement, the anode electrode 33b of the third semiconductor chip 33 is electrically coupled to the cathode electrode 34a of the fourth semiconductor chip 34 via the electrode pattern 24 and the bonding wire 43. Further, an anode electrode 34b formed on the second face of the fourth semiconductor chip 34 and the second electrode terminal 12 are coupled through a bonding wire 44.

As described above, the first semiconductor chip 31, the second semiconductor chip 32, the third semiconductor chip 33, and the fourth semiconductor chip 34 are connected in series between the first electrode terminal 11 serving as a cathode electrode terminal and the second electrode terminal 12 serving as an anode electrode terminal. Accordingly, where the first semiconductor chip 31, the second semiconductor chip 32, the third semiconductor chip 33, and the fourth semiconductor chip 34 are diodes each having a withstand voltage of 3.3 kV, the withstand voltage of the semiconductor apparatus is 13.2 kV, which is equal to 3.3 kV×4. The entirety of the structure formed in this manner is covered with a resin portion 50. Namely, the resin portion covers the first face of the first electrode terminal 11, the first semiconductor chip 31, the second semiconductor chip 32, the third semiconductor chip 33, the fourth semiconductor chip 34, and part of the second electrode terminal 12. The resin portion 50 is formed by transfer molding in which a thermosetting resin having an epoxy resin as a main base material is used.

In the present embodiment, the first semiconductor chip 31 is mounted on the first face 11a of the first electrode terminal 11, and the second semiconductor chip 32, the third semiconductor chip 33, and the fourth semiconductor chip 34 are mounted on the first face 20a of the substrate 20. Further, the substrate 20 is mounted on the first face 11a of the first electrode terminal 11. A step with a height equal to the thickness t of the substrate 20 is thus provided between the first face 11a of the first electrode terminal 11 with the first semiconductor chip 31 mounted thereon and the first face 20a of the substrate 20 on which the second semiconductor chip 32, the third semiconductor chip 33, and the fourth semiconductor chip 34 are mounted. As a result, the provision of an additional creepage distance corresponding to the thickness t of the substrate 20 allows the first semiconductor chip 31 to be brought closer to the substrate 20. Namely, the distance between the first semiconductor chip 31 and the substrate 20 in the Yl-Y2 direction can be shortened by an amount equal to the thickness t of the substrate 20 in the Z1-Z2 direction, which serves to downsize the semiconductor apparatus.

From the viewpoint of withstand voltage, the second semiconductor chip 32, the third semiconductor chip 33, and the fourth semiconductor chip 34, which are disposed on the first face 20a of the substrate 20, are preferably arranged in a straight line. Specifically, as illustrated in FIG. 2, an alignment in a straight line in the Yl-Y2 direction is preferable. An alignment of a plurality of semiconductor chips in a straight line allows the region in which the plurality of semiconductor chips are attached to be narrowed while maintaining high-voltage tolerance, thereby serving to downsize the semiconductor apparatus.

The semiconductor apparatus according to the present embodiment may be such that the third electrode terminal 13 illustrated in FIG. 2 and the first electrode terminal 11 are coupled to each other through a bonding wire (not shown). Further, the first semiconductor chip 31, the second semiconductor chip 32, the third semiconductor chip 33, and the fourth semiconductor chip 34 may be a transistor such as a high-voltage MOSFET or bipolar transistor, instead of a high-voltage diode. In order to provide a small-size high-voltage semiconductor device, the semiconductor material constituting the first semiconductor chip 31, the second semiconductor chip 32, the third semiconductor chip 33, and the fourth semiconductor chip 34 is preferably an SiC semiconductor or the like having a wider bandgap than Si. It may be noted that the first semiconductor chip 31, the second semiconductor chip 32, the third semiconductor chip 33, and the fourth semiconductor chip 34 are power semiconductor devices.

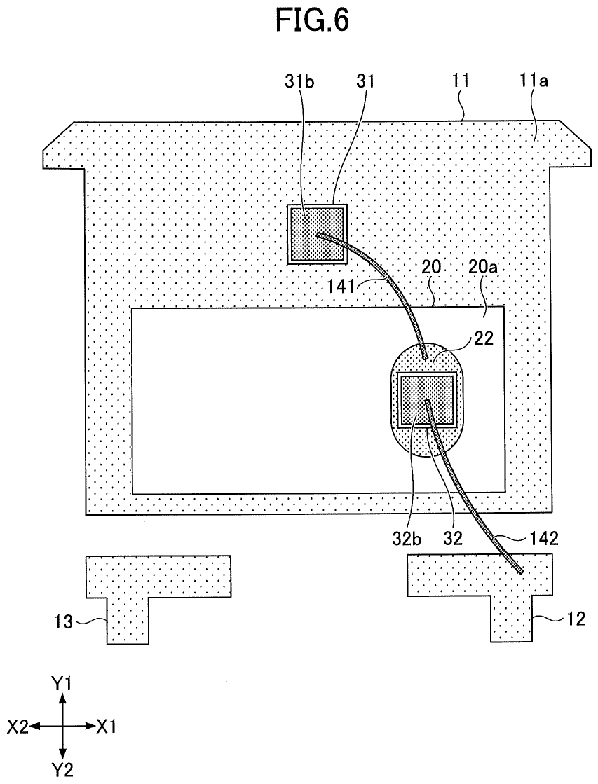

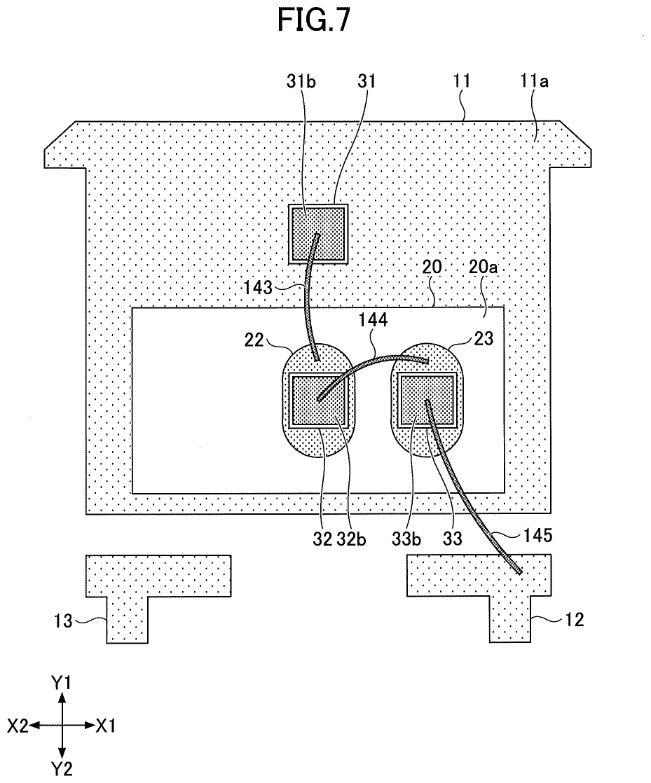

The semiconductor apparatus according to the present embodiment has an advantageous effect in downsizing the semiconductor apparatus in accordance with the height of the substrate 20 even in the case in which only one semiconductor chip is mounted on the first face 20a of the substrate 20 as illustrated in FIG. 6. In the case in which the number of semiconductor chips mounted on the first face 20a of the substrate 20 is two as illustrated in FIG. 7, shaping the electrode patterns in a form without angles provides an advantageous effect.

In the semiconductor apparatus illustrated in FIG. 6, a single electrode pattern 22 is formed on the first face 20a of the substrate 20, and this electrode pattern 22 is connected to the second semiconductor chip 32. In this structure, the anode electrode 31b of the first semiconductor chip 31 and the electrode pattern 22 are coupled through a bonding wire 141, and the anode electrode 32b of the second semiconductor chip 32 and the second electrode terminal 12 are coupled through a bonding wire 142.

In the semiconductor apparatus illustrated in FIG. 7, two electrode patterns 22 and 23 are formed on the first face 20a of the substrate 20, wherein the electrode pattern 22 is connected to the second semiconductor chip 32, and the electrode pattern 23 is connected to the third semiconductor chip 33. The anode electrode 31b of the first semiconductor chip 31 and the electrode pattern 22 are coupled through a bonding wire 143, and the anode electrode 32b of the second semiconductor chip 32 and the electrode pattern 23 are coupled through a bonding wire 144. In this structure, further, the anode electrode 33b of the third semiconductor chip 33 and the second electrode terminal 12 are coupled through a bonding wire 145.

Although one or more embodiments have heretofore been described, any particular embodiments are non-limiting, and various variations and modifications may be made without departing from the scopes defined by the claims.

### DESCRIPTION OF REFERENCE SYMBOLS

10 semiconductor apparatus
11 first electrode terminal
11a first face
11 second face
12 second electrode terminal
20 substrate
20a first face
20b second face
21 insulator substrate
22, 23, 24 electrode pattern
22a straight-line section
22b curved-line section
25 electrode pattern
31 first semiconductor chip
31a cathode electrode
31b anode electrode
32 second semiconductor chip
32a cathode electrode
32b anode electrode
33 third semiconductor chip
33a cathode electrode
33b anode electrode
34 fourth semiconductor chip
34a cathode electrode
34b anode electrode
41, 42, 43, 44 bonding wire
50 resin portion

1. A semiconductor apparatus, comprising:
an electrode terminal;
a substrate disposed on the electrode terminal and made of an insulating material;
a first power semiconductor device disposed on the electrode terminal; and
a second power semiconductor device disposed on the substrate,
wherein the first power semiconductor device and the second power semiconductor device are connected in series.

2. The semiconductor apparatus as claimed in claim 1, further comprising a third power semiconductor device disposed on the substrate, wherein the first power semiconductor device, the second power semiconductor device, and the third power semiconductor device are connected in series.

3. The semiconductor apparatus as claimed in claim 2, wherein a plurality of electrode patterns are formed on a surface of the substrate,
wherein the second power semiconductor device and the third power semiconductor device are disposed on and connected to the respective electrode patterns, and
wherein a shape of the electrode patterns includes a curved line.

4. The semiconductor apparatus as claimed in claim 2, further comprising a fourth power semiconductor device disposed on the substrate,
wherein the first power semiconductor device, the second power semiconductor device, the third power semiconductor device, and the fourth power semiconductor device are connected in series, and
wherein the second power semiconductor device, the third power semiconductor device, and the fourth power semiconductor device are aligned in a straight line on the substrate.

5. The semiconductor apparatus as claimed in claim 1, wherein the insulating material includes at least one kind selected from aluminum nitride, silicon nitride, silicon carbide, and diamond.

6. The semiconductor apparatus as claimed in claim 1, wherein the power semiconductor devices are made of an SiC semiconductor.

7. The semiconductor apparatus as claimed in claim 3, further comprising a fourth power semiconductor device disposed on the substrate,
wherein the first power semiconductor device, the second power semiconductor device, the third power semiconductor device, and the fourth power semiconductor device are connected in series, and
wherein the second power semiconductor device, the third power semiconductor device, and the fourth power semiconductor device are aligned in a straight line on the substrate.

8. The semiconductor apparatus as claimed in claim 2, wherein the insulating material includes at least one kind selected from aluminum nitride, silicon nitride, silicon carbide, and diamond.

9. The semiconductor apparatus as claimed in claim 3, wherein the insulating material includes at least one kind selected from aluminum nitride, silicon nitride, silicon carbide, and diamond.

10. The semiconductor apparatus as claimed in claim 4, wherein the insulating material includes at least one kind selected from aluminum nitride, silicon nitride, silicon carbide, and diamond.

11. The semiconductor apparatus as claimed in claim 7, wherein the insulating material includes at least one kind selected from aluminum nitride, silicon nitride, silicon carbide, and diamond.

12. The semiconductor apparatus as claimed in claim 2, wherein the power semiconductor devices are made of an SiC semiconductor.

13. The semiconductor apparatus as claimed in claim 3, wherein the power semiconductor devices are made of an SiC semiconductor.

14. The semiconductor apparatus as claimed in claim 4, wherein the power semiconductor devices are made of an SiC semiconductor.

15. The semiconductor apparatus as claimed in claim 5, wherein the power semiconductor devices are made of an SiC semiconductor.

16. The semiconductor apparatus as claimed in claim 7, wherein the power semiconductor devices are made of an SiC semiconductor.

17. The semiconductor apparatus as claimed in claim 8, wherein the power semiconductor devices are made of an SiC semiconductor.

18. The semiconductor apparatus as claimed in claim 9, wherein the power semiconductor devices are made of an SiC semiconductor.

19. The semiconductor apparatus as claimed in claim 10, wherein the power semiconductor devices are made of an SiC semiconductor.

20. The semiconductor apparatus as claimed in claim 11, wherein the power semiconductor devices are made of an SiC semiconductor.
